(19) United States
(12) Patent Application Publication
(10) Pub. No.: US 2024/0152554 A1
(43) Pub. Date: May 9, 2024

(54) SYSTEM AND METHODS FOR GENERATING CONTEXTUAL GRAPHS AND INTEGRATED USES THEREOF

(71) Applicant: Samuel Howes, South Portland, ME (US)

(72) Inventor: Samuel Howes, South Portland, ME (US)

(21) Appl. No.: 18/496,266

(22) Filed: Oct. 27, 2023

Related U.S. Application Data
(60) Provisional application No. 63/422,030, filed on Nov. 3, 2022.

(51) Int. Cl. G06F 16/901; G06F 30/20

(52) U.S. Cl. CPC G06F 16/9024; G06F 30/20

(57) ABSTRACT

A computer system for generating contextual graphs, revolutionizing information visualization and comprehension is disclosed herein. This system combines a user-friendly graphical user interface, a computing device, and a force-profile to craft intuitive, interactive contextual graphs. Users input concepts or terms, transformed into nodes, and define relationships between them, realized as links. The force-profile may influence the positioning, size, and significance of nodes and links, offering an engaging visualization experience. The system may allow users to explore paths, fostering an understanding of complex associations. Furthermore, the system may identify gaps and anomalies in graphs, encouraging comprehensive data exploration. In short, the computer system and methodologies disclosed herein may empower users to communicate and convey thoughts through dynamic, interactive contextual graphs, transcending conventional information representation.

### BACKGROUND OF THE INVENTION

The present invention relates generally to generating a contextual graph and methods of interacting with a context graph. More particularly, the present disclosure relates to a computer system providing for the contextual graph generation, display, and user interaction.

Individuals naturally associate or link events, terms, ideas in a unique way in their brains. This information is then recalled as needed based on various triggering and training associated with memory recall. As Humans, we use several communication mechanisms to convey what we are thinking. To be able to generate a contextual graph based on the individual's association can be a useful mechanism and provide yet another additional communication tool. This tool can be used in a variety of ways including helping others understand better how an individual looks at certain concepts.

Therefore, what is needed is a computer system and methodology for generating contextual graphs and integrated uses thereof having all of the further described features and advantages.

### SUMMARY OF THE INVENTION

The subject matter of this application may involve, in some cases, interrelated products, alternative solutions to a particular problem, and/or a plurality of different uses of a single system or article.

In yet another embodiment a method of simulating configured behaviors applied to a graph comprising the steps of: 1) providing a plurality of nodes, with each of the plurality of nodes optionally having a link to at least one other node of the plurality of nodes, wherein each node is representative of a concept and each link is representative of a relationship between two concepts; and 2) modifying the position of at least one node or the length of at least one link by applying a force profile to each of the nodes and links, wherein the nodes are treated as particles.

In the above method, the length of each link can be determined by the application of the force-profile.

In the above method, each node can have a significance, and the significance can be an input to the force-profile.

In some instances, significance of each node can be determined by the number of links a particular node has.

In another variation to the above method each link can add an amount of energy to the graph.

The energy in the graph flows to and collects at nodes. The significance of a particular node can be based on the collection of energy at that particular node.

Regardless of how the significance of each node is determined, the significance of each node can be displayed as a particular size, shape or color.

In the above method the force-profile is physics based.

The force-profile above can include at least one of the following forces: gravity, charge, centering, radial, positioning, spring, and collision.

Alternatively or additionally, the force-profile can include at least one user configured or created force.

In another embodiment, a method of generating a contextual graph and simulating configured behaviors applied to the contextual graph comprising the steps of: 1) receiving user inputs via an interface of one or more concepts; 2) converting each concept into an individual node, wherein each node is configured to be responsive to forces like a particle; 3) linking nodes together based on a user linking input; 4) displaying each node and link as it is received; 5) modifying the position of at least one node or the length of at least one link by applying a force profile to each of the nodes and links each time a new user input or user linking input is received.

In yet another embodiment, a computer system for generating contextual graphs comprising: 1) a monitor with a graphical user interface; 2) a computing device connected to the monitor, the computing device having a central processing unit and a memory; 3) the central processing unit being operable to execute instructions stored on the memory in order to perform a method for generating a contextual graph; 4) a plurality of user input devices connected to the computing device; and 5) the central processing unit is also operable to display nodes and links on the graphical user interface.

These aspects of the invention are not meant to be exclusive and other features, aspects, and advantages of the present invention will be readily apparent to those of ordinary skill in the art when read in conjunction with the following description, appended claims, and accompanying drawings.

### BRIEF DESCRIPTION OF DRAWINGS

The patent or application file contains at least one drawing executed in color. Copies of this patent or patent application publication with color drawing(s) will be provided by the Office upon request and payment of the necessary fee.

The foregoing and other objects, features, and advantages of the invention will be apparent from the following description of particular embodiments of the invention, as illustrated in the accompanying drawings in which like reference characters refer to the same parts throughout the different views.

The drawings are not necessarily to scale, emphasis instead being placed upon illustrating the principles of the invention.

FIG. 1 illustrates a flowchart illustrating a methodology of applying a force-profile to modify the links and nodes of a graph;

FIGS. 2A-H illustrate an example of the evolution of changes, including positioning, size/color of each of the nodes and links as the contextual relationship is applied;

FIGS. 3A-T illustrates more specifically the significance of a particular node and how it evolves based on a mathematical formula, such as a Fibonacci sequence;

FIGS. 4A-B illustrate examples of a generated contextual graph including highlighting a particular node to be analyzed;

FIGS. 5A-B illustrate additional examples of generated contextual graphs, positioning and significance can be seen between the various nodes;

FIG. 6 illustrates a methodology of generating a contextual graph and simulating configured behaviors applied to the contextual graph flowchart;

FIGS. 7A-B illustrate an interface for generating a contextual graph where a force-profile is utilized.

FIG. 8 illustrates an interface highlighting a particular path of a generated contextual graph.

FIG. 9 illustrates one embodiment of a computer system for performing the methodologies described herein.

### DETAILED DESCRIPTION OF THE INVENTION

The detailed description set forth below in connection with the appended drawings is intended as a description of presently preferred embodiments of the invention and does not represent the only forms in which the present disclosure may be constructed and/or utilized. The description sets forth the functions and/or the sequence of steps for constructing and operating the invention in connection with the illustrated embodiments.

As discussed briefly above, as Humans, we use several communication mechanisms to convey what we are thinking. To be able to generate a contextual graph based on the individual's association can be a useful mechanism and provide yet another additional communication tool to provide greater insights into understanding from both the creator and the observer's perspective. Furthermore, to be able to apply a force-profile and in particular a force-profile that utilizes or models natural forces can be useful when applying to an existing graph, as well as a user-generated graph, as another mechanism of interpreting and conveying information.

In one embodiment, the computer system for performing the methods described herein may include a non-transitory computer readable medium or memory, which contains instructions allowing and instructing at least one central processing unit (“CPU” or “processor”) to carry out the steps required during system operation. This non-transitory computer readable medium or memory may be housed within a computing device, or may be accessible through an electronic communication system, such as a network. When used herein the term “network” refers to any system of interconnected electronic devices, such as, a cellular communication network or the Internet. Connections in the network may be wired or wireless.

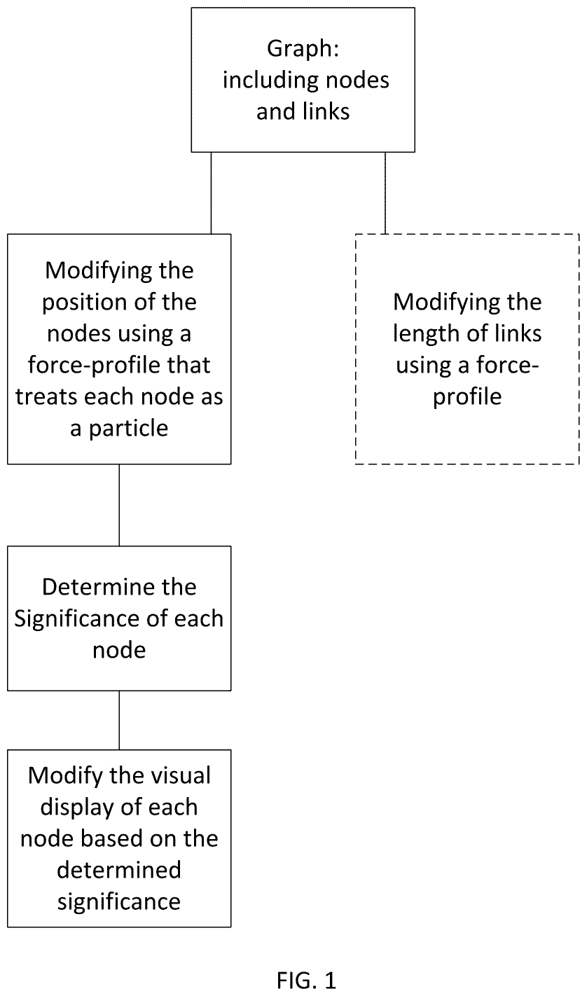

FIG. 1 illustrates a flowchart illustrating a methodology of applying a force-profile to modify the links and nodes of a graph. As noted above, this can be applied to a graph that already exists with nodes and links that represent relationships or to a graph that is being generated in real-time by a user to visually convey the modified graph. In following the methodology, the position of one or more nodes is modified upon using a force-profile that treats each node similar to that of particle. Then the significance of each node can be determined and a modified visual display of each node can be modified. Each of these steps, how they are performed and the resulting actions will become clearer by reviewing the additional figures and description. It should be noted that an alternative modification to the lengths of each link can also occur, as a result of utilizing the force-profile.

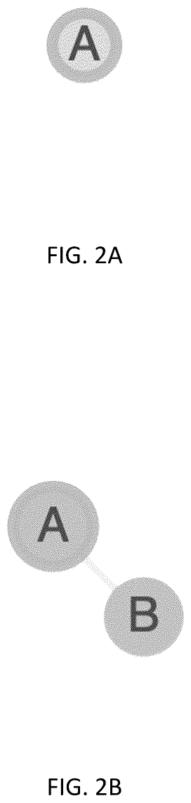

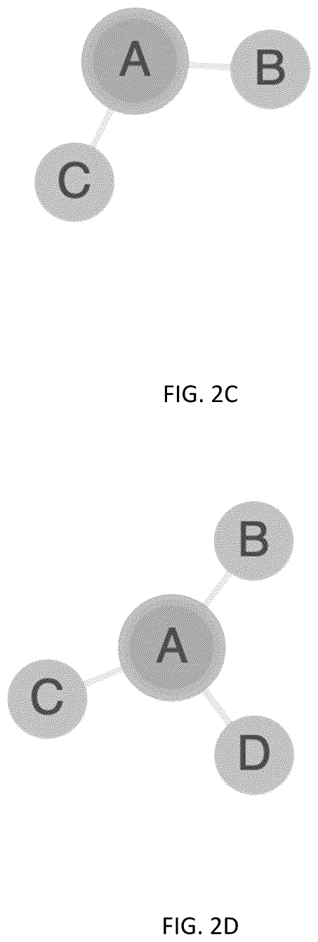

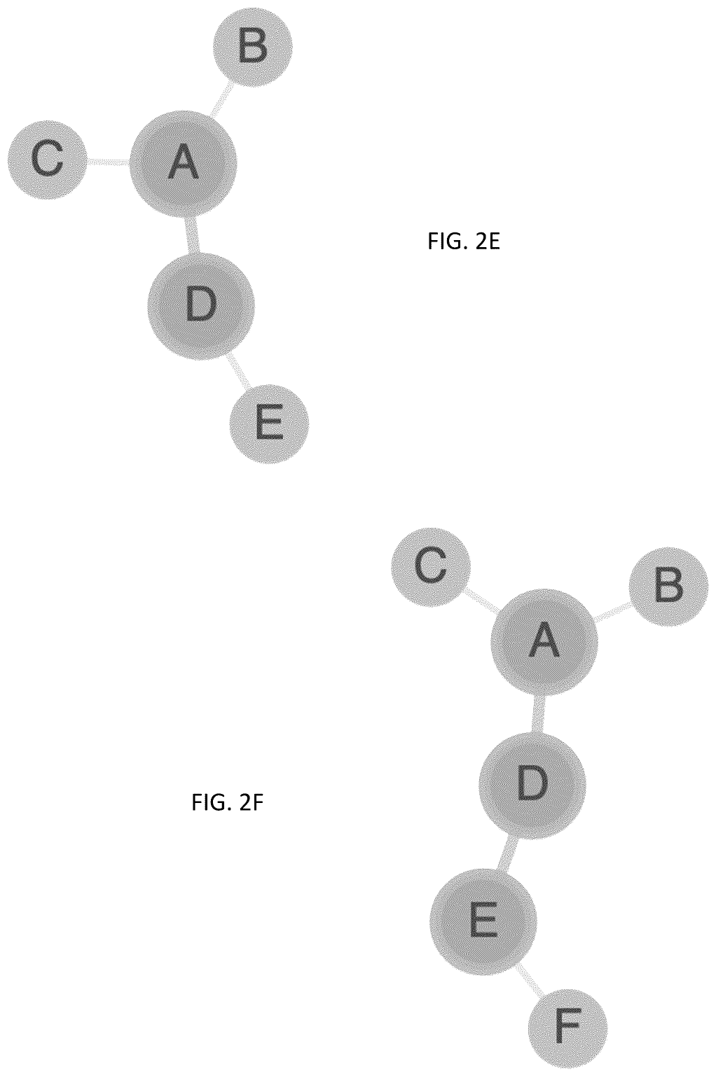

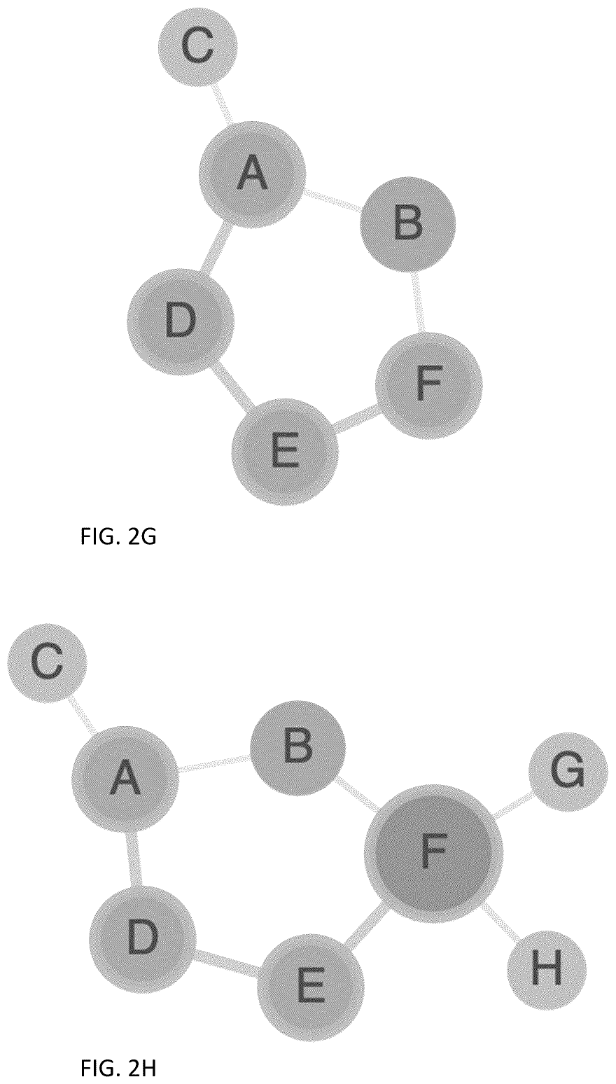

To further convey the change and effects on a graph, FIGS. 2A-H have been provided to illustrate an example of the evolution of changes, including positioning, size/color of each of the nodes and links as the contextual relationship is applied. Starting first with FIG. 2A a single node “A” is displayed, since this is a single node being treated like a particle there is not much of change, but rather this is used to illustrate a starting point. In FIG. 2B, another node “B” is added, along with a linking relationship, whereupon applying the force-profile modifies the position, and updates the significance of each node. The significance here is being shown by a change of color and an increase in size. It should be noted that there can be various ways of visually demonstrating significance, such as using size, color, or shape, shading and various other visual indicators. One or more of these visual indicators may be utilized. For these examples shown, color and size are being displayed.

FIGS. 2C-D illustrate the next phases of the evolution of the graph, as the “C” node is now linked to A, and then the “D” node. Interestingly to note, that when C node is added, A changes color an increase in size, but when D is added, A remains the same color and size. This can be a function of the force-profile that illustrates energy levels, which can be based on a mathematical formula, such as a Fibonacci sequence, which can be utilized to mirror similar energy or growth patterns in nature. Though the Fibonacci sequence is utilized in these examples, other formulas used to model energy and growth can also be used.

FIGS. 2E-F illustrate how the positions of each node change again, as well as the changing of the significance of node D, once node E is connected to D, which in effect gives energy or significance to node D and allows it visually modify. Then in FIG. 2F node E makes a similar change in color and increase in size as node F, is linked to Node E, so now it visually appears that nodes A, D, and E are the same size and color. A technically has more connected to it, but hasn't reached that next level in the Fibonacci sequence, thus it hasn't increase in size or changed in color.

Finally in FIGS. 2G-H, something different occurs as node B, previously only linked to A is connected to F, which causes both B and F to now change in color and size. An enclosure is generated with nodes A, B, D, E, and F and the spacing is reflective of other aspects of the force-profile, which will be described in more detail below. Then nodes G and H are added in FIG. 2H, which cause node F to now reach a new level, which is displayed by a color and size change. The repositioning affects of adding nodes G and H, cause the rest of the nodes to reposition and again are the result of the various force-profile aspects. The highlighting of path A, D, E and F is only for display purposes and any particular path might be highlighted.

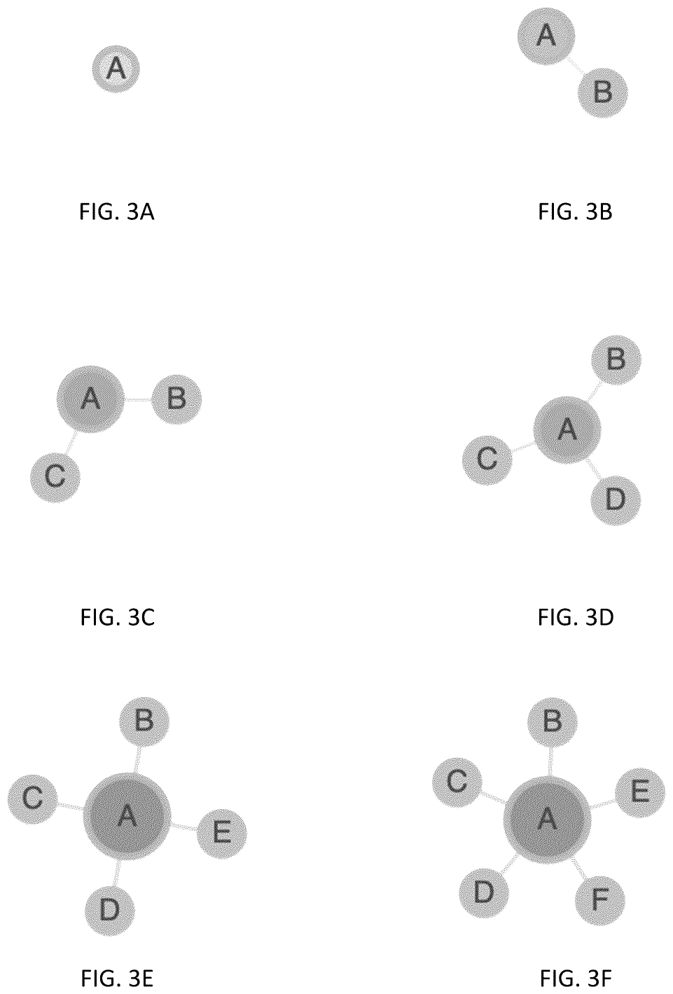

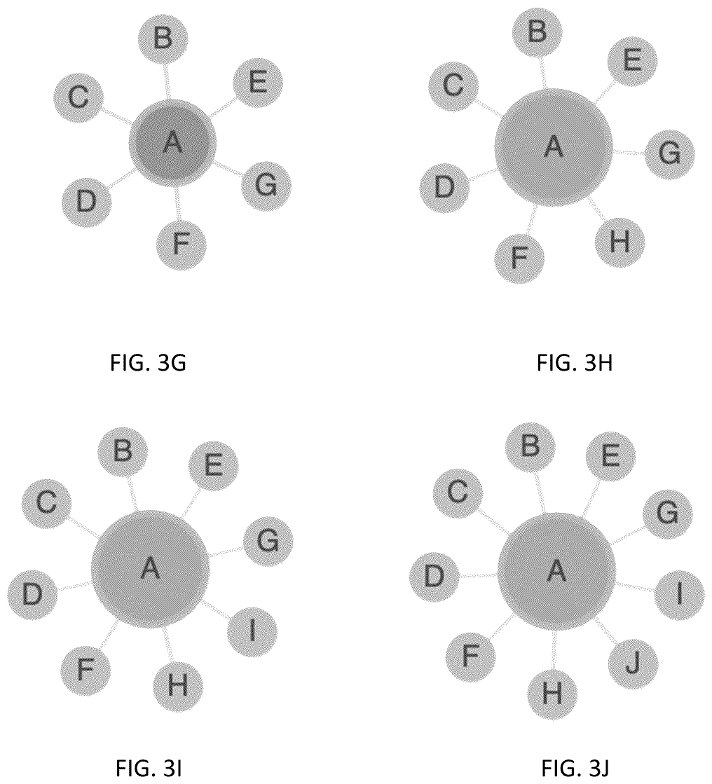

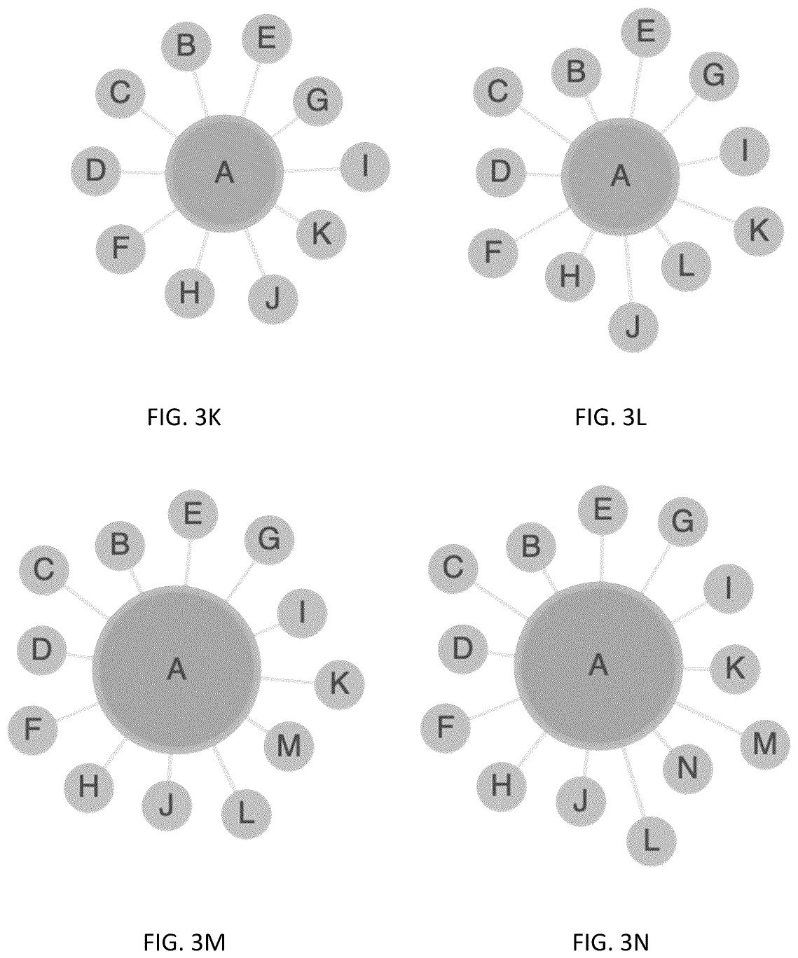

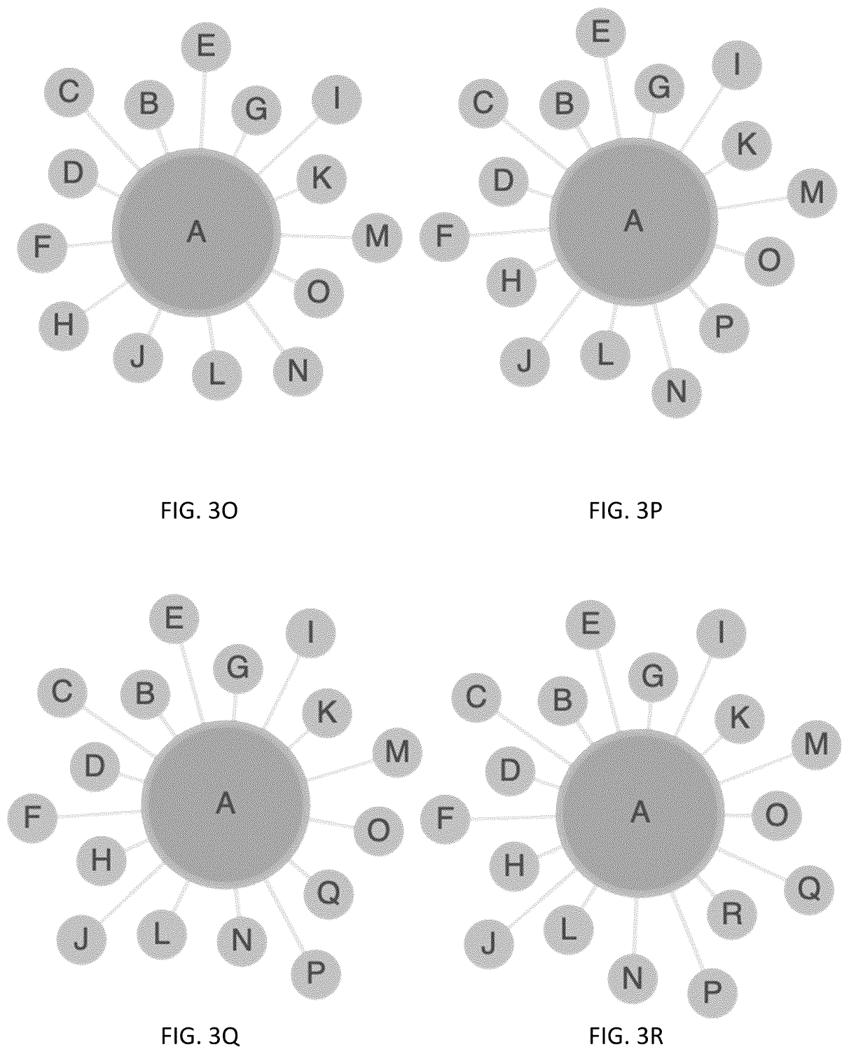

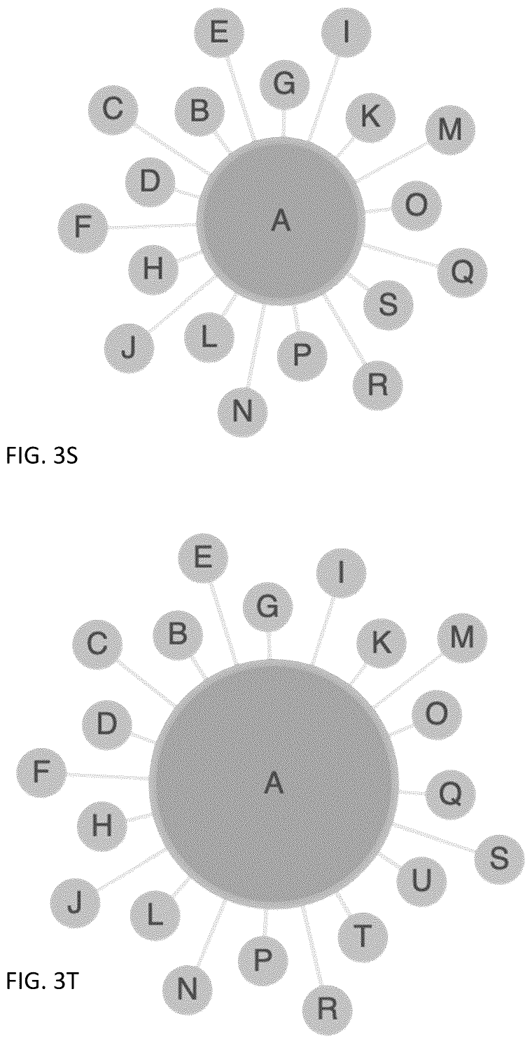

FIGS. 3A-T illustrates more specifically the significance of a particular node and how it evolves based on a mathematical formula, such as a Fibonacci sequence noted above. Instead of linking nodes to other nodes, each new node is linked to node A, and it can be seen how node A changes in color and size based on this Fibonacci sequence. The force profile also, causes each of the non-A nodes to be positioned about node A with each addition. In viewing the various FIGS. 3A-T, one can see that no change occurs from FIG. 3C to 3D, but once a fourth node is added a new significance is reached. This maintained until finally enough nodes at FIG. 3H are added, which causes node A to advance to the next energy level, which again is visually displayed using color and size. From FIG. 3H to 3L node A maintains the same size, but finally at FIG. 3M a new significance is reached. This new significance lasts from 3M to 3S, where finally enough new nodes have been added to reach another significance level.

It is known in the mathematical community that the Fibonacci sequence is a set of integers (the Fibonacci numbers) that starts with a zero, followed by a one, then by another one, and then by a series of steadily increasing numbers. The sequence follows the rule that each number is equal to the sum of the preceding two numbers. The first ten numbers in the sequence include 0, 1, 1, 2, 3, 5, 8, 13, 21, 34. Thus, if each node or particle represents an integer being added then it can readily be seen how the growth or change of significance evolves accordingly.

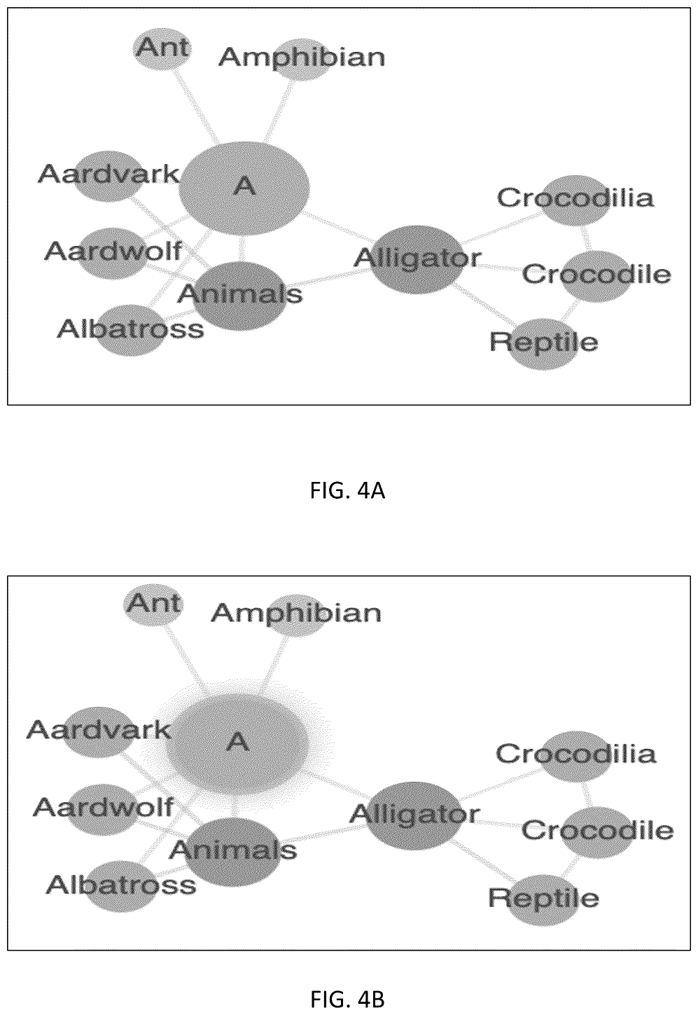

FIGS. 4A-B illustrate examples of a generated contextual graph including highlighting a particular node to be analyzed. Here 4 different energy levels or significance are being displayed, based again on the connections and energy each node is receiving.

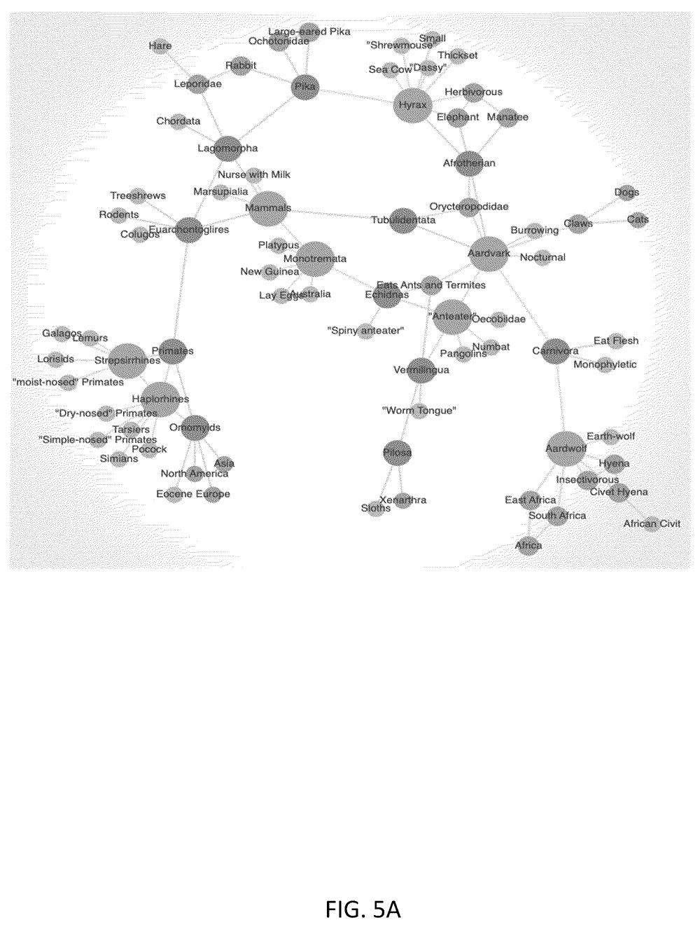

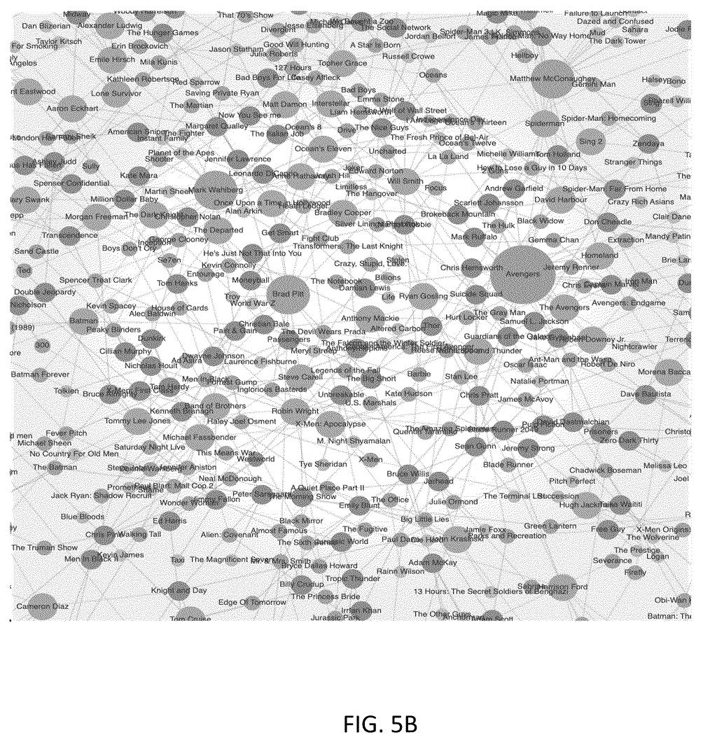

FIGS. 5A-B illustrate additional examples of generated contextual graphs, positioning and significance can be seen between the various nodes, with each of these graphs that include a lot more nodes and links. Again, the significance of each node is being displayed and readily apparent. The more significant nodes tend to draw the viewer's attention and can help with interpreting the contextual graph. FIG. 5B is even more complex and is a contextual graph based on actors and movies that the user has linked together. Here a number of different analyses can be derived, including proximity of the Avengers node to the Brad Pitt, and what that means. Alternatively, the distance of Mark Wahlberg to Avengers versus Brad Pitt to Avengers could be analyzed, as well as a myriad of other combinations. Each of these comparisons and derivations are a direct result of the graph being generated utilizing a force-profile.

As noted above, each graph can have a particular force-profile applied to it, which treats each node as a particle and as new relationships and nodes are introduced utilizes the force-profile to cause a change to the graph, which has previously been demonstrated. Some of the elements or forces the force-profile can include at least one of the following forces: gravity, charge, centering, radial, positioning, spring, and collision. A gravity force can be modeled similar to the theory of gravity. A charge force can be modeled similar to the charge force of a particular particle or atom. A centering force can apply a force on each of the particles about a center of the display, which center can be shifted and or based on center of gravity in some force-profiles. A radial force can push out radially from a particular node to cause other connecting nodes to be radially aligned about that node. The charge of node, which can be affected by the energy level of a node, can have an affect on the radial force. A positioning force can be similar to a centering force, in that a particular position on the graph gets a particular amount of force applied to it. A spring force, can be based on the spring-force constant equation of F=kx. A collision force can be based on inertia, which can in part be derived from the significance of each node. In some instances, a user-generated force can also be entered, which may or may not reflect a force a nature.

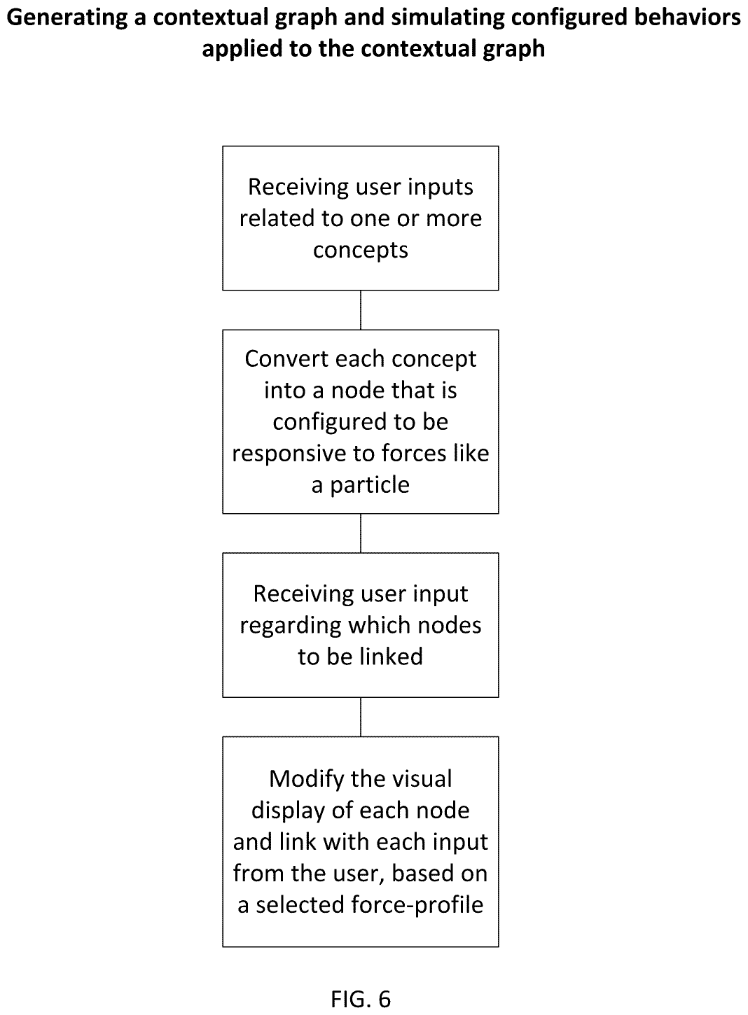

FIG. 6 illustrates a methodology of generating a contextual graph and simulating configured behaviors applied to the contextual graph flowchart. Here the system receives user inputs related to one or more concepts, for example like the actors and movies graph of FIG. 5B. The system and methodology then convert each concept into a node that is responsive to forces like a particle would be responsive to forces. The system and methodology then receive inputs regarding the links or relationships between each of the nodes and a modified visual display of the arrangement of each those nodes is generated based on the given force-profile. Additionally, the significance of each node can be displayed, such as using the visual display techniques described above.

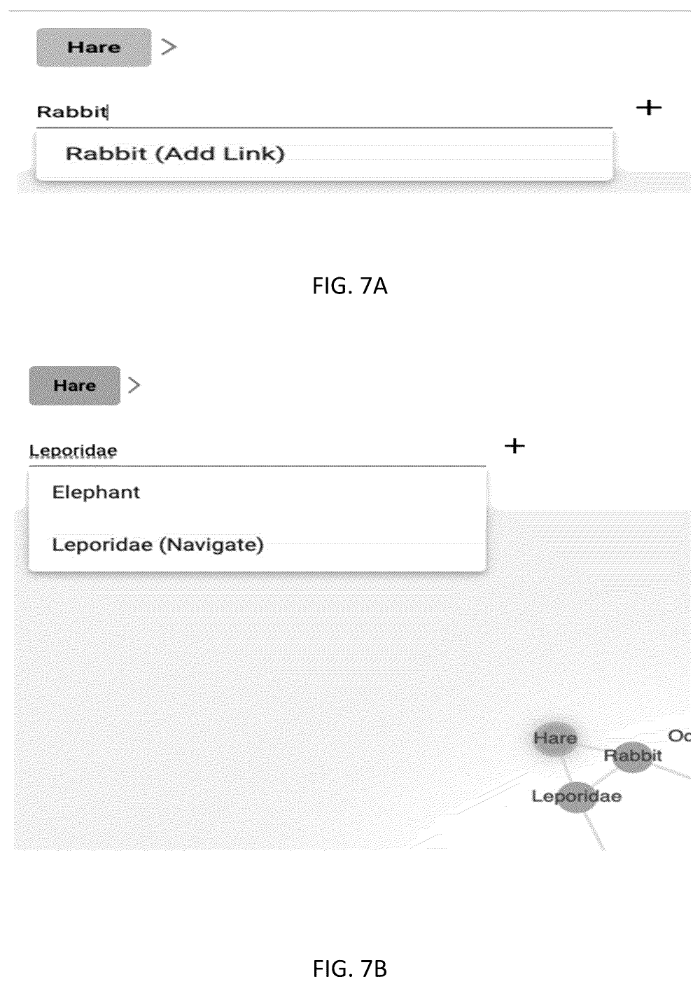

To further illustrate how the methodology of FIG. 6 might be implement, FIGS. 7A-B are provided to illustrate an interface for generating a contextual graph where a force-profile is utilized. Here the concept Hare was created and turned into a node. The user then types in another concept rabbit to be linked to the node Hare in FIG. 7A. In FIG. 7B the user adds the concept Leporidae to be linked to the Hare node as well and the display of the contextual graph is updated and modified according to a force-profile.

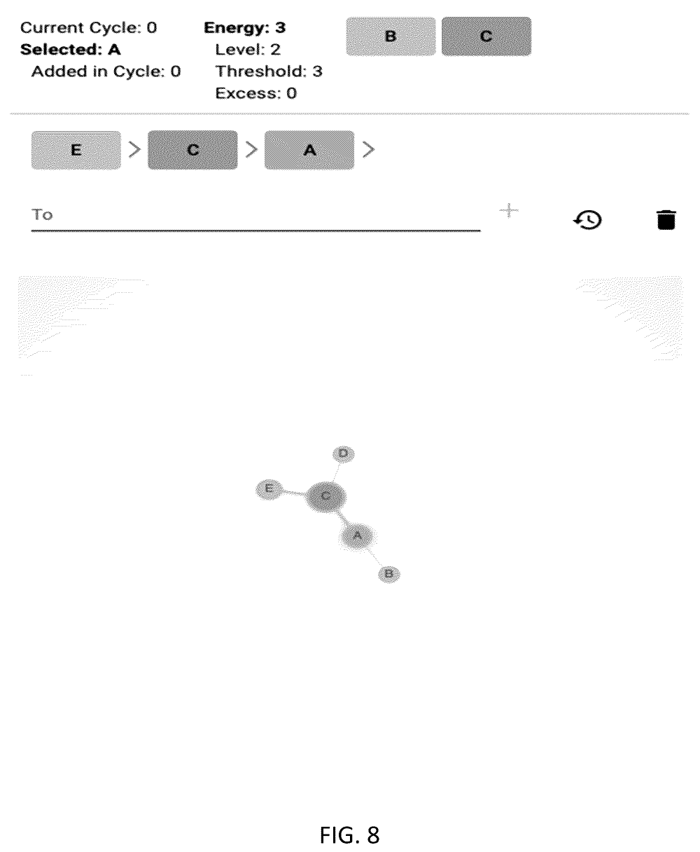

Once a graph is generated, the user can then select various nodes, to highlight a particular path. FIG. 8 illustrates such an interface for highlighting a particular path of a generated contextual graph. The user selects E, then selects C, which is connected to E, and then A which is connected to C, and as each connection is selected a corresponding highlighting of the nodes on the displayed graph appears. It should also be noted that various information about the energy levels can be displayed about particular nodes while exploring a particular graph.

This navigating of graphs generated using force-profiles can be very valuable in many ways. For example, and referring back to FIG. 5A, which illustrates a user-generated contextual graph. The user has previously created an Aardvark concept, which is represented by a node, which is connected to burrowing, which is then connected to claws. At this point the user can select the term claws and create new connections, such as dogs and cats, which then stem from claws, thus in the contextual graph, the user can see how their association of aardvarks to cats or dogs has been created.

Thus, we can see by utilizing the system and methodologies above a user can implement a method of generating a contextual graph comprising the steps of: 1) entering a first term generated by the user, wherein the first is represented by a node on a display; 2) linking to the first node a second node, which represents a second term or thought; 3) determining a length of the link between the first node and the second node based on the energy of each node, wherein each node increases in energy based on the number of direct links thereto; and 4) augmenting the size of each node based on the energy of each node.

Once a contextual graph is created, a user can highlight certain nodes and generated a highlight path between the selected nodes. This highlighting enables the user to understand the pathway of the graph creators' understanding. This visual highlighting can also be isolated, where the rest of the nodes are hidden, and it can also be exported.

Another advantage of the generated contextual graphs is that it can identify “blank” or unfilled areas. This can be used as a prompt to focus on surrounding nodes to identify additional connections the user might or rather that are missing. Thus, the user generated contextual graphs can be used as an exploratory tool. Another advantage of the tool, is that it can be used to identify other anomalies or inconsistencies. This can be realized using historical information or ancillary contextual graphs, which are 1) created by the same user and/or 2) graphs created by other users which can be used to generate a learning algorithm that is then used to identify potential anomalies in the graph and prompt the user to explore those areas further.

Another advantage of the generated contextual graphs herein are the weighting forces that can be applied to help determine the placement of each of the nodes with respect to each other. These weighting forces can include: Gravity, Charge, Spring Force: F=kx, which includes “Desired” length of spring or “Desired” force constant, a Centering Force, a setup that pushes to outside out from the middle, a Collision force, a Radial force, a force to Push nodes to align to a circle, and a Fixed force. One or more of these forces can be used to cause the nodes to be visually positioned with respect to each other. Several of these forces or modeled after naturally occurring forces, which can help align with the natural ways humans see and think about their surroundings.

One of the primary ideas being conveyed in this description as well as the accompanying figures is the transformation of the graph as if its nodes are particles susceptible to forces. Treating ideas as particles allows for an entirely different way of conveying, understanding and organizing graphical information.

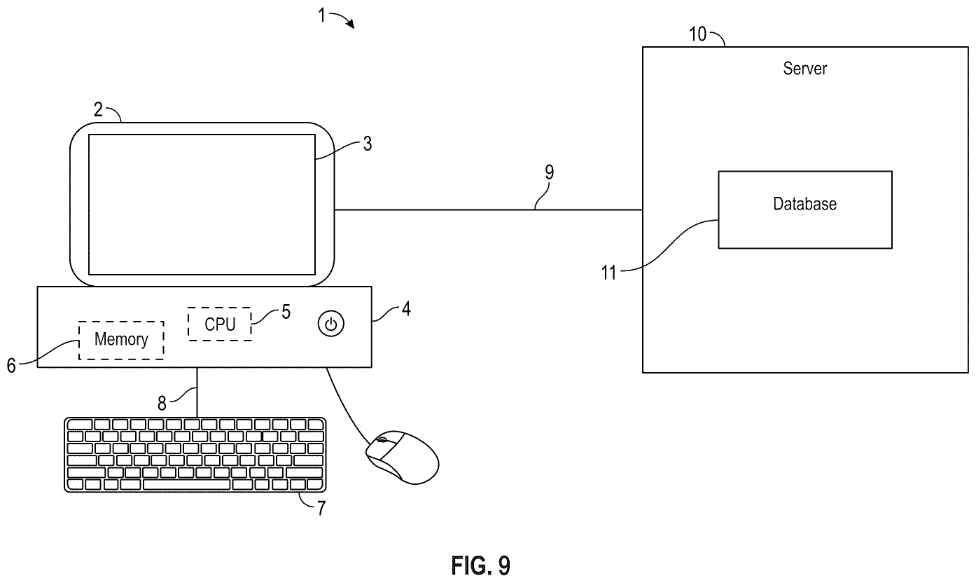

Turning now to FIG. 9, one embodiment of the computer system 1 for generating contextual graphs is shown. In this embodiment, the computer system comprises several key components, including, but not limited to a monitor 2 and a graphical user interface 3. The monitor 2 facilitates user access to the system 1 by providing a graphical user interface 3 through which users interact with the system. As used herein, the term “monitor” encompasses any electronic display or visual output device capable of presenting graphical or textual information to a user. Such monitors may include, but are not limited to, desktop computer monitors, laptop screens, tablet displays, mobile phone screens, and any other portable or fixed electronic screens or displays designed for human interaction and information presentation.

The computer system 1 also includes a computing device 4, which serves as the core processing unit. The computing device 4 comprises essential components, including, but not limited to, a central processing unit or processor 5 and a memory 6. The central processing unit 5 is responsible for executing various instructions and performing computational tasks. The memory 6 stores instructions and data that are essential for the operation of the computer system and/or the contextual graph generation. These stored instructions are executed by the processor 5 during operation of the system 1.

Similar to the term “monitor,” as used herein, the term “computing device” encompasses any electronic device with a memory, processor, or user interface. This generally includes apparatuses with the capability to process data, execute instructions, and perform computational tasks. Such computing devices may include, but are not limited to, desktop computers, laptops, tablet computers, mobile phones, servers, embedded systems, wearable devices, and any other electronic systems or hardware configured for information processing, storage, and communication.

To facilitate user interaction with the computer system 1, user input devices 7 are provided. These devices 7 include a mouse and a keyboard, but the term “input device” is meant to encompass any hardware or components designed to facilitate user interaction and input with a computing device, including, but not limited to, touchscreens. The input devices 7 are connected to the computing device 4 through electronic communication lines 8. These communication lines can be either short-range wireless connections, such as a Bluetooth® connection, or hard-wired connections.

As previously described, the computer system 1 includes a computing device 4 and a monitor 2. In this context, the computing device 4 is configured to cause the monitor 2 to display a website or application providing for contextual graph generation on the user interface 3. This user interface 3 provides users with a platform to interact with contextual graphs and utilize the methodologies described herein.

To enable communication and data transfer between the computing device 4 and the monitor 2, an electronic communication line 9 is established. This line 9 may encompass both wired and wireless connections, including connections to computerized device networks, such as the Internet, cellular networks, and the like.

The electronic communication line 9 connects the computing device 4 to a server 10 specifically designed to support the contextual graph generation functionality. This server 10 contains a database 11 that stores the necessary files and information required for the operation of the contextual graph generation website or application. Such files and information may include historical data, statistical models, user preferences, and any other relevant information. This information may also be stored, entirely or in part, on the memory 6 of the computing device 4.

In some embodiments, the force profile of the contextual graph plays a crucial role in shaping the visual representation of nodes and links on the user interface. The force profile may encompass various factors that influence the width and visibility of individual links, as well as the size, color, and font of the associated text for each node. The interplay of forces, including gravity, charge, centering, radial, positioning, spring, and collision, may exert significant influence on the layout of nodes exhibited on the user interface. These force may help determine crucial aspects of the graph's appearance, such as node spacing, inward pressure, node size, link strength, link distance, centering strength, link bonding, and the like. As a result, the force profile not only governs the dynamic interplay between elements within the graph but may also shape the user's experience in comprehending complex contextual relationships.

It should be expressly understood that the intricacies of the force profile extend beyond mere aesthetics, impacting the usability and interpretability of the contextual graph. Each of the forces, from gravity's pull to the nuanced dynamics of collision and radial forces, may contribute to a comprehensive system of rules that guide the arrangement and behavior of nodes and links.

For instance, in some embodiments, the spring force may control the desired length of links and the force constant, influencing link strength and distance. Meanwhile, charge-based forces may evoke visual analogs to the charges of particles, determining the repulsion or attraction between nodes and thus affecting node spacing and distribution. These meticulously calibrated forces, akin to the natural forces encountered in the physical world, may harmonize the display to mimic intuitive human cognition and spatial awareness. As a result, the force profile may ensure that the contextual graph is not only visually appealing but also a powerful tool for conveying intricate relationships, enabling users to explore and comprehend complex data structures with ease.

In one embodiment, after the generation of a contextual graph comprising multiple nodes and links, the computer system may be operable to save the interconnected information for the graph in a database. Within this database, not only may the information for the nodes and links preserved, but the specific link paths between nodes may also be retained. This ensures that the contextual graph may be regenerated, with all its constituent elements in precisely the same order and arrangement as the initial generation. This feature may provide users with a tool for preserving and revisiting their previously constructed contextual graphs, facilitating a deep and ongoing exploration of the underlying relationships displayed thereon.

One of the technical challenges encountered in the display of contextual graphs, particularly those containing a vast number of nodes and links (i.e., hundreds or thousands), is the limited availability of screen space and the limited processing power for graphical user interfaces. These problems can often lead to slow or choppy user interfaces due to the sheer computational complexity of rendering and managing such intricate visual information networks.

An automatic zoom-in, zoom-out feature may provide a solution to the limited availability of screen space that plagues computer systems generally. The automatic zoom-in, zoom-out feature may dynamically adjust the level of detail visible on the user interface, ensuring that users can navigate and explore even the most extensive graphs efficiently.

For example, when dealing with a densely interconnected graph, the computer system may be operable to automatically zoom-in on a particular subset of nodes and links. This capability may address the issue of visual clutter and ensures that users can work with complex graphs without feeling overwhelmed. Conversely, the computer system may also be operable to automatically scale down the rendering of nodes and links (i.e., zoom-out), allowing users to see the entire graph within the limited screen space, providing more of a comprehensive overview of the contextual graph. In some embodiments, the computer system may only be operable to zoom-in or zoom-out after receiving an input to do so.

Next, to address the challenge of limited processing power, one technical solution may be the implementation of a self-optimizing rendering algorithm. A self-optimizing rendering algorithm may utilize two distinct algorithms: 1) a rendering algorithm, and 2) an optimization algorithm. The rendering algorithm may first assess the size and intricacy of the contextual graph. It may then selectively apply one or more rendering techniques tailored to the graph's complexity, such as occlusion culling to eliminate non-visible elements and/or level-of-detail rendering to display only what's necessary.

The optimization algorithm may provide a comprehensive quality control mechanism to ensure the proper functioning of the rendering algorithm by constantly monitoring the rendering process, checking for anomalies and performance bottlenecks. It may assess various rendering aspects, such as frame rate, rendering speed, and graphical fidelity. If any discrepancies or slowdowns are detected, the optimization algorithm may trigger an adjustment in the rendering process, such as reconfiguring rendering parameters or prioritizing specific rendering techniques. It may also evaluate the rendering outcome against a pre-defined performance benchmark to ensure that the system is meeting any expected standards. This dynamic process of active monitoring and fine-tuning of the rendering algorithm by the optimization algorithm may ensure that the interface remains responsive by reducing the computational load during graph rendering, thus delivering a smooth and efficient user experience, even when handling large and intricate contextual graphs.

The present disclosure also provides a solution to the problems stemming from the inherent complexity of having a binary machine interpret Human language. For example, at least one embodiment of the computer system may be operable to identify and generate a prompt to explore a connection or an anomaly in a contextual graph displayed on a user interface. In such an embodiment, the computer system may utilize a machine learning algorithm, particularly a Large Language Model (“LLM”), to accurately interpret the Human language text displayed on the contextual graph.

A LLM is a machine learning system that is designed to process Human text based on extensive training on large amounts of text data. In one embodiment, the text data may be stored in a database on a server, and a processor may ultimately execute the steps required for training the computer system. A LLM generally works through a two-step process: pre-training and fine-tuning.

In the pre-training phase, the LLM may be exposed to a vast corpus of text from one or more databases, where it may learn statistical patterns, syntax, grammar, and semantic relationships present in Human text. The LLM may capture word associations, context and even complex linguistic constructs during this initial phase.

In the second phase, fine-tuning may tailor the LLM for specific tasks or domains, such as sentiment analysis. During this phase, the LLM may be trained on labeled datasets where connections or anomalies between groupings of nodes and links are already identified as examples. Fine-tuning may adjust the LLM's internal parameters to optimize its performance. This process allows the LLM to capture the rich and varied ways people express their opinions and emotions in text, resulting in more accurate analysis outcomes. Having a computer processor and/or server utilize a LLM may provide one solution to the problem of having a binary machine interpret Human text to display a prompt to explore a connection or an anomaly in a generated contextual graph.

While the principles of the invention have been described herein, it is to be understood by those skilled in the art that this description is made only by way of example and not as a limitation as to the scope of the invention. Other embodiments are contemplated within the scope of the present invention in addition to the exemplary embodiments shown and described herein. Modifications and substitutions by one of ordinary skill in the art are considered to be within the scope of the present invention. Further, any features or aspects of a particular embodiment can be used or combined with any features or aspects of any other embodiment where appropriate.

1. A method of simulating configured behaviors applied to a graph comprising the steps of:
providing a plurality of nodes, with each of the plurality of nodes optionally having a link to at least one other node of the plurality of nodes, wherein each node is representative of a concept and each link is representative of a relationship between two concepts; and
modifying the position of at least one node or the length of at least one link by applying a force profile to each of the nodes and links, wherein the nodes are treated as particles.

2. The method of simulating configured behaviors applied to a graph of claim 1, wherein the length of each link is determined by the application of the force-profile.

3. The method of simulating configured behaviors applied to a graph of claim 1, wherein each node has a significance, and wherein the significance is an input to the force-profile.

4. The method of simulating configured behaviors applied to a graph of claim 3, wherein the significance of each node is determined by the number of links a particular node has.

5. The method of simulating configured behaviors applied to a graph of claim 3, wherein each link adds an amount of energy to the graph.

6. The method of simulating configured behaviors applied to a graph of claim 5, wherein the energy in the graph flows to and collects at nodes.

7. The method of simulating configured behaviors applied to a graph of claim 6, wherein the significance of a particular node is based on the collection of energy at that particular node.

8. The method of simulating configured behaviors applied to a graph of claim 7, wherein the significance of each node is displayed as a particular size, shape or color.

9. The method of simulating configured behaviors applied to a graph of claim 1, wherein the force-profile is physics based.

10. The method of simulating configured behaviors applied to a graph of claim 1, wherein the force-profile includes at least one of the following forces: gravity, charge, centering, radial, positioning, spring, and collision.

11. The method of simulating configured behaviors applied to a graph of claim 1, wherein the force-profile includes at least one user configured or created force.

12. A method of generating a contextual graph and simulating configured behaviors applied to the contextual graph comprising the steps of:
receiving user inputs via an interface of one or more concepts;
converting each concept into an individual node, wherein each node is configured to be responsive to forces like a particle;
linking nodes together based on a user linking input;
displaying each node and link as it is received;
modifying the position of at least one node or the length of at least one link by applying a force profile to each of the nodes and links each time a new user input or user linking input is received.

13. A computer system for generating contextual graphs, comprising:
a monitor with a graphical user interface;
a computing device connected to the monitor, the computing device having a central processing unit and a memory;
wherein the central processing unit is operable to execute a plurality of instructions stored on the memory in order to perform a method for generating a contextual graph;
a plurality of user input devices connected to the computing device; and
wherein the central processing unit is operable to display a plurality of nodes and a plurality of links on the graphical user interface.

14. The computer system of claim 13 wherein the plurality of user input devices comprises at least one of a keyboard, a mouse, or a touchscreen for user interaction.

15. The computer system of claim 13 wherein the plurality of nodes represents a plurality of concepts or terms, and the plurality of links represents relationships between the plurality of concepts or terms.

16. The computer system of claim 13 wherein a plurality of forces affect a position or a significance of the plurality of nodes on the graphical user interface.

17. The computer system of claim 13 wherein the method for generating a contextual graph comprises applying a force-profile to modify a layout and an appearance of the plurality of nodes and the plurality of links.

18. The computer system of claim 13 wherein the method for generating a contextual graph comprises an input selecting and highlighting at least one node out of the plurality nodes or a link path within the contextual graph.

19. The computer system of claim 13 wherein the central processing unit is operable to add, modify, or delete at least one of the plurality of nodes or one of the plurality of links in real-time on the graphical user interface.

20. The computer system of claim 13 wherein the central processing unit is operable to identify and generate a prompt to explore at least one of a connection or an anomaly in the contextual graph.
